(19) United States
(12) Patent Application Publication
(10) Pub. No.: US 2022/0357962 A1
(43) Pub. Date: Nov. 10, 2022

(54) METHOD FOR OPERATING A SYSTEM HAVING A PLURALITY OF CAX MODULES

(71) Applicant: Ford Global Technologies, LLC, Dearborn, MI (US)

(72) Inventor: Mahdi Garoosi, Cologne (DE)

(73) Assignee: Ford Global Technologies, LLC, Dearborn, MI (US)

(21) Appl. No.: 17/725,624

(22) Filed: Apr. 21, 2022

(30) Foreign Application Priority Data
May 6, 2021 (DE) 102021111818.2

(51) Int. Cl. G06F 9/445

(52) U.S. Cl. CPC G06F 9/44526

(57) ABSTRACT

A method for operating a system having a plurality of computer-aided design (CAD), computer-aided engineering (CAE), and/or computer-aided testing (CAT) modules (CAx modules) is provided. The method includes identifying a CAx module which has a data transmission connection to an add-on module, and assigning a control dataset to the identified CAx module, wherein the assigned control dataset assigns a user input to at least one operating command of the identified CAx module. The method further includes loading a user input, determining the operating command associated with the loaded user input, and transmitting the determined operating command to the identified CAx module.

### CROSS-REFERENCE TO RELATED APPLICATIONS

This patent application claims priority to German Patent Application No. 102021111818.2, filed May 6, 2021, which is hereby incorporated by reference in its entirety.

### BACKGROUND

The present disclosure relates to a method for operating a system having a plurality of CAx modules.

The term CAx is understood to mean different computer-supported work steps or technologies, such as e.g. CAD (computer-aided design), CAE (computer-aided engineering) or CAT (computer-aided testing).

A person working with CAx modules of this type must frequently switch back and forth between different CAx modules since each CAx module is designed for a specific purpose or a specific task. Each of the CAx modules has a set of operating commands to which a set of respective user inputs is assigned. However, the user inputs are not uniformly assigned in each case to the same or to related operating commands. This means that the user, when switching from one CAx module to another CAx module, must remember the respective user input in order to execute a desired operating command. Consequently, operating errors can occur which result in time losses.

An interface for a mobile device which is intended to simplify navigation in a CAD model is known from US 2016/147414 A1.

A system for selecting objects from a 3D scene for presenting different alternatives is known from US 2007/159477 A1.

A need therefore exists to indicate ways in which the operation of a system having a plurality of CAx modules can be simplified.

### SUMMARY

An implementation of the present disclosure provides a method for operating a system having a plurality of CAx modules, having the steps of: identifying a computer-aided design, engineering, or testing (CAx) module which has a data transmission connection to an add-on module, assigning a control dataset to the identified CAx module, wherein the assigned control dataset assigns a user input to at least one operating command of the identified CAx module, loading a user input, determining the operating command associated with the loaded user input, and transmitting the determined operating command to the identified CAx module.

An add-on module, also referred to alternatively as a plug-in, is understood to mean a software extension or an additional module in the form of a software component which extends or modifies existing software. For this purpose, application programming interfaces (APIs) of existing software can be accessed, by means of which third parties can program extensions of this type.

With the add-on module, a translator can be installed which assigns user inputs to the respective operating commands according to the control dataset. A user can thus control the currently used CAx module with the user inputs that are familiar to him in order to execute the respective desired operating command.

The operation of a system having a plurality of CAx modules can thus be significantly simplified.

According to one implementation, at least two CAx modules are identified, and the same user input is assigned to the respective operating commands by means of the respective control datasets for at least two CAx modules. In other words, in the case of an operation with at least two CAx modules, it is ensured that a user input is the same for both CAx modules. The user can thus control both CAX modules in the same way with the user input that is familiar to him in order to execute the respective desired same operating command. This simplifies, in particular, working with CAx modules of this type when switching back and forth between them.

In a further step for the assignment, a user may assign a user input manually to an operating command and the control dataset may be generated in a further step. The user can therefore input and then use his desired and/or customary assignment of user inputs to operating commands.

In a further step for the assignment, a CAx module may be selected with a control dataset to which a predetermined user input is assigned, and, in a further step, the predetermined user inputs of a further CAx may be assigned their control dataset in order to generate the control dataset. In other words, the assignment of the user input to operating commands of the first CAx module may be used as the master assignment or template assignment which is then transferred onto other CAx modules. A user can thus transfer his desired and/or customary assignment of user inputs to operating commands which he knows and/or is familiar with from one CAx system onto one or more other CAx modules.

In a further step for the assignment, operating commands may be classified according to their function and, in a further step, the same user inputs m assigned to operating commands assigned to the same class in order to generate the control dataset. Automatic classification methods, for example, such as Random Forest, for example, can be used for the classification. Artificial neural networks can also be used for the classification. Artificial neural networks (ANN for short) are networks consisting of artificial neurons. These neurons (also referred to as node points) of an artificial neural network are arranged in layers and are normally interconnected in a fixed hierarchy. The neurons are usually connected between two layers, but in rarer cases within a layer also. An artificial neural network of this type is trained during a training phase before its deployment. The artificial neural network is modified during the training phase so that it generates associated output patterns for specific input patterns. This can be done by means of monitored learning, unmonitored learning, reinforcement learning, or stochastic learning. A trained artificial neural network offers the advantage that it benefits from its learning capability, its parallelism, its error tolerance, and its resistance to faults. The generation of the control dataset can thus be completely automated, i.e., no user intervention is necessary.

The present disclosure also relates to a computer program product, a system (i.e., computing device) for operating a plurality of CAx modules, and an add-on module for a system of this type.

### BRIEF DESCRIPTION OF THE DRAWINGS

FIG. 1 shows a schematic representation of a screen view with a plurality of CAx modules.

FIG. 2 shows a schematic representation of a system for operating a plurality of CAx modules.

FIG. 3 shows a schematic representation of further details of the system shown in FIG. 2.

FIG. 4 shows a schematic representation of a method sequence for operating the system shown in FIGS. 2 and 3.

### DETAILED DESCRIPTION

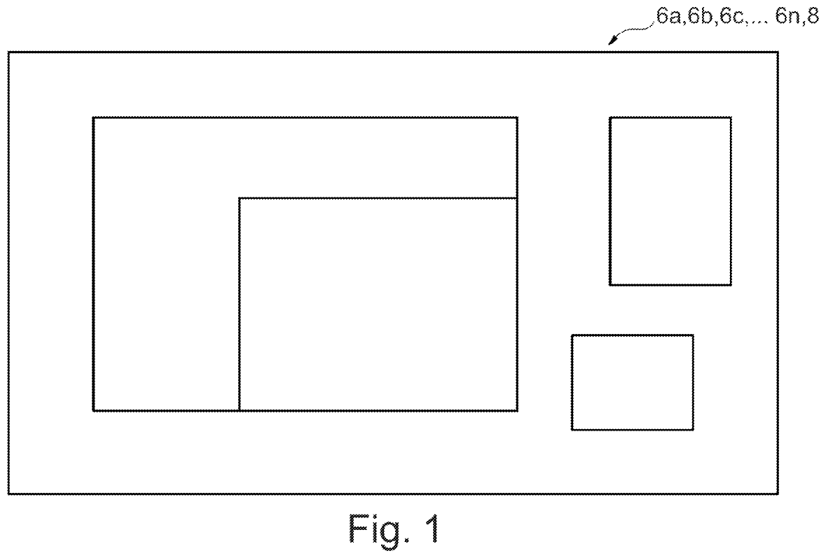

Reference is first made to FIG. 1.

A screen view of a human machine interface (HMI 8) is shown with a plurality of CAx modules 6a, 6b, 6c, . . . 6n.

A person working with such a plurality of CAx modules 6a, 6b, 6c, . . . 6n must frequently switch back and forth between different CAx modules 6a, 6b, 6c, . . . 6n, since each CAx module 6a, 6b, 6c, . . . 6n is designed for a specific purpose or a specific task.

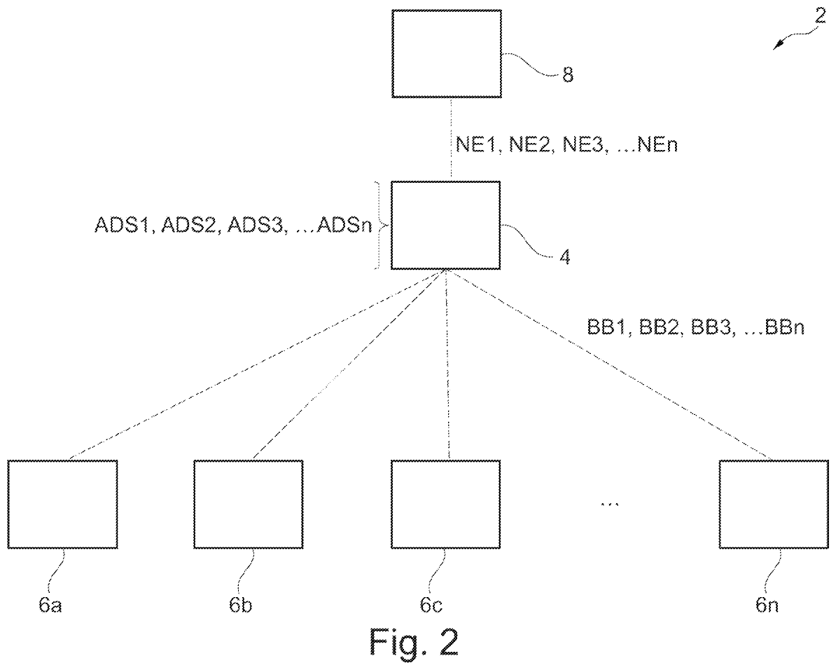

Each of the CAx modules 6a, 6b, 6c, . . . 6n has a set of operating commands BB1, BB2, BB3, . . . BBn to which a set of respective user inputs NE1, NE2, NE3, . . . NEn is assigned. However, the user inputs NE1, NE2, NE3, . . . NEn are not assigned uniformly in each case to the same or to related operating commands BB1, BB2, BB3, . . . BBn. This means that the user, when switching from one CAx module 6a, 6b, 6c, . . . 6n to another CAx module 6a, 6b, 6c, . . . 6n, must remember the respective user input NE1, NE2, NE3, . . . NEn in order to execute a desired operating command BB1, BB2, BB3, . . . BBn. Consequently, operating errors can occur which result in time losses. A system 2 for operating such a plurality of CAx modules 6a, 6b, 6c, . . . 6n with which the operation of such a plurality CAx modules 6a, 6b, 6c, . . . 6n can be significantly simplified will now be explained with additional reference to FIG. 2.

For this purpose, the system 2, along with the plurality of CAx modules 6a, 6b, 6c, . . . 6n, has an add-on module 4 which has a data transmission connection to the plurality of CAx modules 6a, 6b, 6c, . . . 6n. Furthermore, the add-on module 4 also has a data transmission connection to the HMI 8.

The system 2, the add-on module 4, and the plurality of CAx modules 6a, 6b, 6c, . . . 6n have hardware and/or software components for the tasks and/or functions described below, such as in the form of a computing device having a processor and a memory storing instructions executable by the processor for accomplishing the tasks and/or functions.

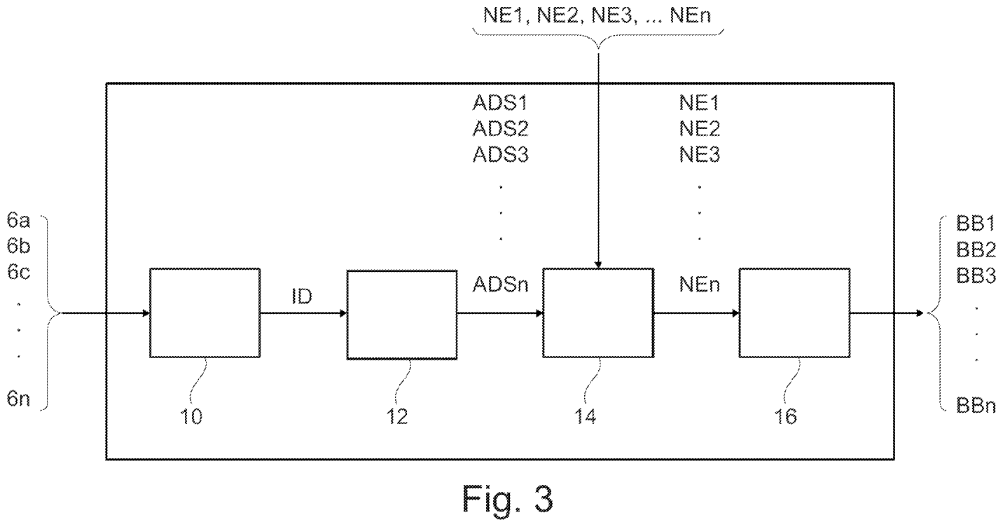

Reference will now be made additionally to FIG. 3 in order to explain components of the add-on module 4. The components of the add-on module 4 can also have hardware and/or software components for the tasks and/or functions described below.

The add-on module 4 is designed to identify a CAx module 6a, 6b, 6c, . . . 6n which has a data transmission connection. This can be done by means of an identification module 10 of the add-on module 4, e.g. during an initialization procedure of the system 2 and/or in response to a commissioning and/or activation of one of the CAx modules 6a, 6b, 6c, . . . 6n. The identification module 10 then provides a respective indicator ID for each identified CAx module 6a, 6b, 6c, . . . 6n.

The add-on module 4 is further designed to load or determine a control dataset ADS1, ADS2, ADS3, . . . ADSn which assigns operating commands BB1, BB2, BB3, . . . BBn to the user inputs NE1, NE2, NE3, . . . NEn. The add-on module 4 has an assignment module 12 for this purpose.

The add-on module 4 is further designed to load a user input NE1, NE2, NE3, . . . NEn which a user actuates by means of the HMI 8, and to determine the operating command BB1, BB2, BB3, . . . BBn associated with the loaded user input NE1, NE2, NE3, . . . NEn, and to transmit the determined operating command BB1, BB2, BB3, . . . BBn to the identified CAx module 6a, 6b, 6c, . . . 6n. The add-on module 4 has an input module 14 for this purpose.

The add-on module 4 and its components are further designed to identify two or more CAx modules 6a, 6b, 6c, 6n. The add-on module 4 and its components are further designed to then assign the same user input NE1, NE2, NE3, . . . NEn to the respective operating commands BB1, BB2, BB3, . . . BBn by means of the respective control datasets ADS1, ADS2, ADS3, . . . ADSn for at least two CAx modules 6a, 6b, 6c, . . . 6n.

In other words, two or more CAx modules 6a, 6b, 6c, . . . 6n can be controlled with identical user inputs NE1, NE2, NE3, . . . NEn in such a way that the same or similar or related commands are executed.

The user inputs NE1, NE2, NE3, . . . NEn can, for example, be the key combination Shift+Alt+LMB which, as the operating command BB1, BB2, BB3, . . . BBn, initiates a rotation of the camera view, the key combination Shift+Alt+RMB which changes a zoom factor, the key combination Shift+Alt+MMB which initiates a camera panning, the key combination Shift+Ctrl+RMB which presents a display of open tasks, or the key combination MMB which effects a movement of a point along the y-axis.

In other words, the control dataset ADS1, ADS2, ADS3, . . . ADSn assigns operating commands BB1,BB2, BB3, . . . BBn to user inputs NE1, NE2, NE3, . . . NEn.

The add-on module 4 can be designed to cause an additional window to appear in the screen content visualized by the HMI 8 for the user in response to the identification of the CAx module 6a, 6b, 6c, . . . 6n.

The user can then assign a user input NE1, NE2, NE3, . . . NEn manually to an operating command BB1, BB2, BB3, . . . BBn by means of this window. On completion of this manual input, the add-on module 4 generates the control dataset ADS1, ADS2, ADS3, . . . ADSn on the basis of the manual inputs of the user. The add-on module 4 can have a control dataset generation module 16 for this purpose. The add-on module 4 can further be designed to select a CAx module 6a, 6b, 6c, . . . 6n with a control dataset ADS1, ADS2, ADS3, . . . ADSn, e.g. the first CAx module 6a, 6b, 6c, . . . 6n which has been activated by the user or has been determined by the user in other ways.

With regard to the further CAx module 6a, 6b, 6c, . . . 6n, its control dataset ADS1, ADS2, ADS3, . . . ADSn is then determined in such a way that user inputs NE1, NE2, NE3, . . . NEn, which are used to control the first CAx module 6a, 6b, 6c, . . . 6n, can similarly be used to control the further CAx module 6a, 6b, 6c, . . . 6n. In other words, the assignment of the user input NE1, NE2, NE3, . . . NEn to the operating commands BB1, BB2, BB3, . . . BBn of the first CAx module 6a, 6b, 6c, . . . 6n is used as the master assignment or template assignment that is then transferred onto other CAx modules 6a, 6b, 6c, . . . 6n. The add-on module 4 can also have a control dataset generation module 16 for this purpose.

The add-on module 4 can further be designed to classify its operating commands BB1, BB2, BB3, . . . BBn according to their function, to assign the same user inputs NE1, NE2, NE3, . . . NEn to operating commands BB1, BB2, BB3, . . . BBn assigned to the same class, and to generate the control dataset ADS1, ADS2, ADS3, . . . ADSn automatically without user intervention. The add-on module 4 can also have a control dataset generation module 16 for this purpose.

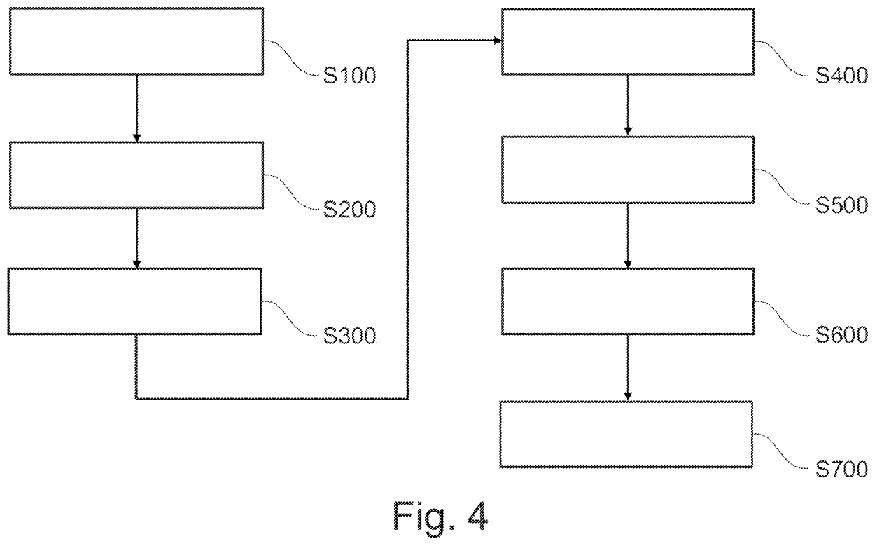

Reference will now be made additionally to FIG. 4 in order to explain a method sequence for operating the system 2 shown in FIGS. 2 and 3.

The method begins with a first step S100 of identifying one or more CAx modules 6a, 6b, 6c, . . . 6n having a data transmission connection to an add-on module 4 by means of the identification module 10 of the add-on module 4.

In a further step S200, a control dataset ADS1, ADS2, ADS3, . . . ADSn is assigned by the assignment module 12 of the add-on module 4 to the identified CAx module 6a, 6b, 6c, 6n, wherein the assigned control dataset ADS1, ADS2, ADS3, . . . ADSn assigns a user input NE1, NE2, NE3, . . . NEn to at least one operating command BB1, BB2, BB3, . . . BBn of the identified CAx module 6a, 6b, 6c, . . . 6n. This can be repeated for a plurality of CAx module 6a, 6b, 6c, . . . 6n according to the number of CAx modules 6a, 6b, 6c, . . . 6n.

In a further step S300, it can be provided for the assignment that a user assigns a user input NE1, NE2, NE3, . . . NEn manually to an operating command BB1, BB2, BB3, . . . BBn, and the control dataset ADS1, ADS2, ADS3, . . . ADSn is generated in a further step S400.

Alternatively or additionally, it can be provided in a further step S300 for the assignment that a CAx module 6a, 6b, 6c, . . . 6n is selected with a control dataset ADS1, ADS2, ADS3, . . . ADSn to which a predetermined user input NE1, NE2, NE3, . . . NEn is assigned, and, in a further step S400, the predetermined user inputs NE1, NE2, NE3, . . . NEn of a further CAx module 6a, 6b, 6c, . . . 6n are assigned their control dataset ADS1, ADS2, ADS3, . . . ADSn in order to generate the control dataset ADS1, ADS2, ADS3, . . . ADSn.

Furthermore, it can also be provided alternatively or additionally, in a further step S300 for the assignment, to classify operating commands BB1, BB2, BB3, . . . BBn according to their function and, in a further step S400, to assign the same user inputs NE1, NE2, NE3, . . . NEn to operating commands BB1, BB2, BB3, . . . BBn assigned to the same class in order to generate to the control dataset ADS1, ADS2, ADS3, . . . ADSn.

According to the present example implementation, at least two CAx modules 6a, 6b, 6c, . . . 6n are identified. The same user input NE1, NE2, NE3, . . . NEn is then assigned to the respective operating commands BB1, BB2, BB3, . . . BBn by means of the respective control datasets ADS1, ADS2, ADS3, . . . ADSn for at least two CAx modules 6a, 6b, 6c, . . . 6n.

In a further step S500, a user input NE1, NE2, NE3, . . . NEn is loaded by the input module 14 of the add-on module 4.

In a further step S600, the operating command BB1, BB2, BB3, . . . BBn associated with the loaded user input NE1, NE2, NE3, . . . NEn is determined by the dataset generation module 16 of the add-on module 4. In a further step S700, the add-on module 4 transmits the determined operating command BB1, BB2, BB3, . . . BBn to the identified CAx module 6a, 6b, 6c, . . . 6n.

In contrast to the present example implementation, the sequence of the steps can also be different. A plurality of steps can also be carried out concurrently or simultaneously. Furthermore, also in contrast to the present example implementation, individual steps can be skipped or omitted.

The operation of the system 2 having a plurality of CAx modules 6a, 6b, 6c, . . . 6n can thus be significantly simplified by the add-on module 4.

### REFERENCE NUMBER LIST

2 System
4 Add-on module
6a CAx module
6b CAx module
6c CAx module
6n CAx module
8 HMI
10 Identification module
12 Assignment module
14 Input module
16 Dataset generation module
ADS1 Control dataset
ADS2 Control dataset
ADS3 Control dataset
ADSn Control dataset
BB1 Operating command
BB2 Operating command
BB3 Operating command
BBn Operating command
ID Identifier
NE1 User input
NE2 User input
NE3 User input
NEn User input
S100 Step
S200 Step
S300 Step
S400 Step
S500 Step
S600 Step
S700 Step

1-12. (canceled)

13. A method for operating a system having a plurality of computer-aided design (CAD), computer-aided engineering (CAE), and/or computer-aided testing (CAT) modules (CAx modules), comprising:
identifying a CAx module which has a data transmission connection to an add-on module;
assigning a control dataset to the identified CAx module, wherein the assigned control dataset assigns a user input to at least one operating command of the identified CAx module;
loading a user input;
determining the operating command associated with the loaded user input; and
transmitting the determined operating command to the identified CAx module.

14. The method according to claim 13, wherein at least two CAx modules are identified, and wherein the same user input is assigned to the respective operating commands by means of the respective control datasets for at least two CAx modules.

15. The method according to claim 14, wherein, for the assignment, a user assigns a user input manually to an operating command in a first step, and the control dataset is generated in a further step.

16. The method according to claim 14, wherein, for the assignment, in a further step, a CAx module is selected with a control dataset to which a predetermined user input is assigned, and, in a further step, the predetermined user inputs of a further CAx module are assigned their control dataset in order to generate the control dataset.

17. The method according to claim 14, wherein, for the assignment, in a further step, operating commands are classified according to their function, and, in a further step, a same set of user inputs are assigned to operating commands assigned to a same class in order to generate the control dataset.

18. A non-transitory computer-readable medium having stored thereon computer-executable instructions to perform the method of claim 13.

19. A computing device comprising a processor and a memory storing instructions executable by the processor to operate a plurality of computer-aided design (CAD), computer-aided engineering (CAE), and/or computer-aided testing (CAT) modules (CAx modules) which have a data transmission connection to an add-on module, wherein the instructions are configured to:
identify a CAx module which has a data transmission connection to an add-on module,
assign a control dataset to the identified CAx module, wherein the assigned control dataset assigns a user input to at least one operating command of the identified CAx module,
load a user input, to determine the operating command associated with the loaded user input, and
transmit the determined operating command to the identified CAx module.

20. The computing device according to claim 19, wherein the instructions are configured to identify at least two CAx modules to assign the same user input to the respective operating commands by means of the respective control datasets for at least two CAx modules.

21. The computing device according to claim 20, wherein the instructions to assign a control dataset further include instruction to:
receive a user input to manually assign to an operating command, and
generate the control dataset in a further step.

22. The computing device according to claim 20, wherein the instructions are configured, for the assignment, to:
select a CAx module with a control dataset to which a predetermined user input is assigned, and
assign the predetermined user inputs of a further CAx module their control dataset in order to generate the control dataset.

23. The computing device according to claim 20, wherein the instructions are configured, for the assignment, to:
classify operating commands according to their function, and
assign a same set of user inputs to operating commands assigned to a same class in order to generate the control dataset.

24. The computing device according to claim 19, wherein the instructions are provided in the add-on module.
